(19) United States
(12) Patent Application Publication
(10) Pub. No.: US 2019/0288129 A1
(43) Pub. Date: Sep. 19, 2019

(54) PHOTOSENSITIVE DETECTING DEVICE CAPABLE OF SIMULTANEOUSLY DETECTING SPECTRA OF DIFFERENT WAVELENGTHS

(71) Applicant: HYTRONIK ELECTRONICS CO., LTD., Huizhou, Guangdong (CN)

(72) Inventor: Yabing Cheng, Huizhou, Guangdong (CN)

(21) Appl. No.: 16/348,865

(22) PCT Filed: Aug. 3, 2017
(86) PCT No.: PCT/CN2017/095896

§ 371 Date: May 9, 2019

(30) Foreign Application Priority Data
May 15, 2017 (CN) PCT/CN2017/084387

(51) Int. Cl. H01L 31/0216; H01L 27/144; G01J 3/02; G01J 3/28

(52) U.S. Cl. CPC H01L 31/02162; G01J 3/2803; G01J 3/0229; H01L 27/1443

(57) ABSTRACT

A photosensitive detecting device capable of simultaneously detecting spectra of different wavelengths comprises a first photosensitive chip (3) covered by a first spectral filtering layer (2), the first spectral filtering layer (2) allowing a light with a wavelength in a first range to pass through in response to a reception from the first photosensitive chip (3), and a second photosensitive chip (6) covered by a second spectral filtering layer (5), the second spectral filtering layer (5) allowing a light with a wavelength in a second range to pass through in response to a reception from the second photosensitive chip (6). The photosensitive detecting device has an advantage of simultaneously detecting various spectra of different wavelengths by one independent device.

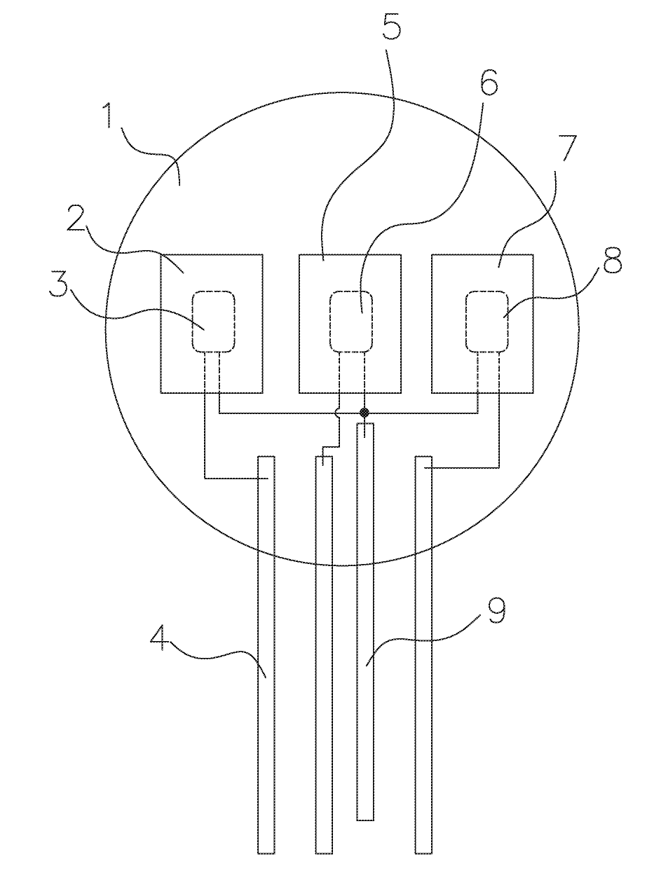

### FIELD OF THE INVENTION

The present invention relates to the field of electronic devices, more particularly to a photosensitive detecting device capable of simultaneously detecting the spectra of different wavelengths, which is capable of simultaneously detecting various spectra of different wavelengths by one individual device.

### BACKGROUND OF THE INVENTION

Photosensitive sensors are widely used for electronic products such as solar lawn lamps, optical-control night lamps, cameras, monitors, light-activated toys, voice and light control switches, video cameras, anti-theft wallets, light-activated musical boxes, musical birthday candles, musical cups, human body induction lamps and human body sensor switches in the field of automatic optical control. Photoelectric sensors, which convert optical signals into electrical signals by means of photosensitive elements, have sensitive wavelengths including infrared wavelength and ultraviolet wavelengths near wavelengths of visible light. Usually, photosensitive sensors can precisely detect lights having wavelengths in a certain range, but meanwhile have poor effect on the detection of lights having wavelengths in other ranges. Since the ambient light usually consists of lights having the spectra at different wavelengths, conventional photosensitive sensors realize different accuracies in the mornings than in the evenings. In the meantime, in order to realize automatic control, sometimes the detection of invisible light is also necessary. Hence, in order to precisely detect the ambient light or detect lights having different wavelengths, existing products have to be arranged simultaneously with two or more photosensitive sensors for the spectra of different wavelengths and thus have to be provided with a plurality of openings, which lead to high cost and imperfect appearance.

### SUMMARY OF THE INVENTION

In order to overcome disadvantages of existing technologies, the present invention aims to provide a photosensitive detecting device capable of simultaneously detecting the spectra of different wavelengths, which is capable of simultaneously detecting various spectra of different wavelengths by one individual device.

To achieve the above goal, the present invention provides a photosensitive detecting device capable of simultaneously detecting spectra of different wavelengths, which comprises a first photosensitive chip covered by a first spectral filtering layer, the first spectral filtering layer allowing a light with a wavelength in a first range to pass through in response to a reception from the first photosensitive chip, and a second photosensitive chip covered by a second spectral filtering layer, the second spectral filtering layer allowing a light with a wavelength in a second range to pass through in response to a reception from the second photosensitive chip.

Preferably, wherein the first photosensitive chip and the second photosensitive chip are arranged on a same printed circuit board, respectively covering the first spectral filtering layer and the second spectral filtering layer, and a package is formed.

Preferably, the first spectral filtering layer and the second spectral filtering layer are configured to allow lights having wavelengths in different ranges to pass through.

Preferably, the first spectral filtering layer may be configured to allow visible lights with wavelengths in a range of 400 nm-700 nm to pass through, and the second spectral filtering layer may be configured to allow invisible lights with wavelengths in a range of 700 nm-1050 nm to pass through.

Preferably, common terminals of the first photosensitive chip and the second photosensitive chip may be connected together and led out by one pin, and the other pins of the first photosensitive chip and the second photosensitive chip are led out separately, and an independent photosensitive detecting device can be packaged.

Preferably, the package may be DIP package or SMD package.

Preferably, a third photosensitive chip covered by a third spectral filtering layer may be provided, the third spectral filtering layer allowing a light with a wavelength in a third range to pass through in response to a reception from the third photosensitive chip.

Preferably, the first photosensitive chip, the second photosensitive chip and the third photosensitive chip are arranged on a same printed circuit board, respectively covering the first spectral filtering layer, the second spectral filtering layer and the third spectral filtering layer, and then the package is formed.

Preferably, the first spectral filtering layer, the second spectral filtering layer and the third spectral filtering layer are configured to allow lights having wavelengths in different ranges to pass through.

Preferably, common terminals of the first photosensitive chip, the second photosensitive chip and the third photosensitive chip may be connected together and led out by one pin, and the other pins of the first photosensitive chip, the second photosensitive chip and the third photosensitive chip are led out separately, and an independent photosensitive detecting device can be packaged.

According to the present invention, two or more than two photosensitive chips for detecting the spectra of corresponding wavelengths are packaged in one device, and respective spectral filtering layers for allowing light with corresponding wavelengths in the spectra to pass through are provided on respective photosensitive chips, such that different photosensitive chips can be used for detecting the spectra of corresponding wavelengths in different ranges, whereby the present invention achieves the goal of simultaneously detecting the spectra of different wavelengths by one individual device, greatly reducing material cost and the space for PCB, solving the problem of providing the products with a plurality of openings for detecting ambient lights in practical application, and having a very vast market foreground.

### BRIEF DESCRIPTION OF THE DRAWINGS

The sole FIGURE is a schematic drawing illustrating a structure according to an embodiment of the present invention.

### DETAILED DESCRIPTION OF ILLUSTRATED EMBODIMENTS

The present invention will be further explained below in detail with reference to drawings and embodiments.

Referring to the FIGURE, a photosensitive detecting device capable of simultaneously detecting the spectra of different wavelengths comprises a first photosensitive chip 3 covered by a first spectral filtering layer 2, the first spectral filtering layer 2 allowing a light with a wavelength in a first range to pass through in response to a reception from the first photosensitive chip 3, a second photosensitive chip 6 covered by a second spectral filtering layer 5, the second spectral filtering layer 5 allowing a light with a wavelength in a second range to pass through in response to a reception from the second photosensitive chip 6, and a third photosensitive chip 8 covered by a third spectral filtering layer 7, the third spectral filtering layer 7 allowing a light with a wavelength in a third range to pass through in response to a reception from the third photosensitive chip 8. Herein, the first photosensitive chip 3, the second photosensitive chip 6 and the third photosensitive chip 8 are arranged on a same printed circuit board 1, respectively covering the first spectral filtering layer 2, the second spectral filtering layer 5 and the third spectral filtering layer 7, and then the packaging is performed.

The present photosensitive detecting device has three photosensitive chips 3, 6 and 8 (in other embodiments two, or four, or more chips may be provided, depending on how many ranges the wavelengths of lights to be detected fall in) for detecting spectra of corresponding wavelengths, which are arranged on the printed circuit board 1 of one individual device and a package can be formed. In addition, the spectral filtering layers 2, 5 and 7 for allowing light with corresponding wavelengths in the spectra to pass through are provided on the surfaces of the three photosensitive chips 3, 6 and 8. Consequently, different photosensitive chips can be used for detecting the spectra of different wavelengths. During manufacturing, common terminals of respective photosensitive chips are connected together inside the device and then led out by one pin 9, and the other pins 4 of respective photosensitive chips are led out separately. Then, an independent photosensitive detecting device can be packaged, which is capable of simultaneously detecting the spectra of different wavelengths by one independent device. It greatly reduces material cost and the space for PCB, solves the problem of providing the products with a plurality of openings for detecting ambient lights in practical application, and has a very vast market foreground.

Referring to the FIGURE, in particular in an embodiment of the photosensitive detecting device capable of simultaneously detecting the spectra of different wavelengths on the basis of the above mentioned solution, the first spectral filtering layer 2 may be configured to allow visible light with wavelengths in a range of 400 nm-700 nm to pass through, and the second spectral filtering layer 5 may be configured to allow invisible light with wavelengths in a range of 700 nm-1050 nm to pass through.

Referring to the FIGURE, in particular in an embodiment of the photosensitive detecting device capable of simultaneously detecting the spectra of different wavelengths on the basis of the above mentioned solution, in order to facilitate identification of pins, the common terminal pin 9 of respective photosensitive chips may be shorter than the other pins 4 of respective photosensitive chips, or, respective pins of respective photosensitive chips may be produced in different colors, so as to facilitate identification during using.

In particular in an embodiment of the photosensitive detecting device capable of simultaneously detecting the spectra of different wavelengths on the basis of the above mentioned solution, the package may be DIP package, or SMD package, or others.

The above description for the photosensitive detecting device capable of simultaneously detecting the spectra of different wavelengths of the present invention is intended to aid in the understanding of the present invention. All the above embodiments are not to limit the invention in any form. The present invention is intended to cover all changes, various modifications, equivalent arrangements, combinations and simplifications included within the principle of the present invention.

1. A photosensitive detecting device capable of simultaneously detecting spectra of different wavelengths, characterized in that, the photosensitive detecting device comprises a first photosensitive chip covered by a first spectral filtering layer, the first spectral filtering layer allowing a light with a wavelength in a first range to pass through in response to a reception from the first photosensitive chip, and at least a second photosensitive chip covered by a second spectral filtering layer, the second spectral filtering layer allowing a light with a wavelength in a second range to pass through in response to a reception from the second photosensitive chip.

2. The photosensitive detecting device capable of simultaneously detecting spectra of different wavelengths according to claim 1, characterized in that, the first photosensitive chip and the second photosensitive chip are arranged on one same printed circuit board, respectively covering the first spectral filtering layer and the second spectral filtering layer, such that a package is formed.

3. The photosensitive detecting device capable of simultaneously detecting spectra of different wavelengths according to claim 1, characterized in that, the first spectral filtering layer and the second spectral filtering layer are configured to allow lights having wavelengths in different ranges to pass through.

4. The photosensitive detecting device capable of simultaneously detecting spectra of different wavelengths according to claim 1, characterized in that, the first spectral filtering layer is configured to allow visible lights with wavelengths in a range of 400 nm-700 nm to pass through, and the second spectral filtering layer is configured to allow invisible lights with wavelengths in a range of 700 nm-1050 nm to pass through.

5. The photosensitive detecting device capable of simultaneously detecting spectra of different wavelengths according to claim 1, characterized in that, common terminals of the first photosensitive chip and the second photosensitive chip are connected together and led out by one pin, and respective other terminals of the first photosensitive chip and the second photosensitive chip are led out separately, such that a package of an independent photosensitive detecting device is formed.

6. The photosensitive detecting device capable of simultaneously detecting spectra of different wavelengths according to claim 2, characterized in that, the package is DIP package or SMD package.

7. The photosensitive detecting device capable of simultaneously detecting spectra of different wavelengths according to claim 1, characterized in that, a third photosensitive chip covered by a third spectral filtering layer is further provided, the third spectral filtering layer allowing a light with a wavelength in a third range to pass through in response to a reception from the third photosensitive chip.

8. The photosensitive detecting device capable of simultaneously detecting spectra of different wavelengths according to claim 7, characterized in that, the first photosensitive chip, the second photosensitive chip and the third photosensitive chip are arranged on one same printed circuit board, respectively covering the first spectral filtering layer, the second spectral filtering layer and the third spectral filtering layer, such that a package is formed.

9. The photosensitive detecting device capable of simultaneously detecting spectra of different wavelengths according to claim 7, characterized in that, the first spectral filtering layer, the second spectral filtering layer and the third spectral filtering layer are configured to allow lights having wavelengths in different ranges to pass through.

10. The photosensitive detecting device capable of simultaneously detecting spectra of different wavelengths according to claim 7, characterized in that, common terminals of the first photosensitive chip, the second photosensitive chip and the third photosensitive chip are connected together and led out by one same pin, and respective other terminals of the first photosensitive chip, the second photosensitive chip and the third photosensitive chip are led out separately, such that a package of an independent photosensitive detecting device is formed.
